(19) United States
(12) Patent Application Publication
(10) Pub. No.: US 2012/0017981 A1
(43) Pub. Date: Jan. 26, 2012

(54) SOLAR CELL AND METHOD FOR MANUFACTURING THE SAME

(76) Inventors: Indo CHUNG, Seoul (KR); Jinah Kim, Seoul (KR); Jeongbeom Nam, Seoul (KR); Juhong Yang, Seoul (KR); Seunghwan Shim, Seoul (KR); Hyungwook Choi, Seoul (KR); Ilhyoung Jung, Seoul (KR); Hyungjin Kwon, Seoul (KR)

(21) Appl. No.: 13/185,908

(22) Filed: Jul. 19, 2011

(30) Foreign Application Priority Data
Jul. 20, 2010 (KR) 10-2010-0069960
Sep. 29, 2010 (KR) 10-2010-0094611

(51) Int. Cl. H01L 31/0236; H01L 31/18

(52) U.S. Cl. 136/256; 438/71; 257/E31.13

(57) ABSTRACT

A solar cell and a method for manufacturing the solar cell are discussed. The solar cell includes a substrate, an emitter layer formed at an incident surface of the substrate, a first electrode part connected to the emitter layer, and a textured surface positioned on the incident surface of the substrate, at which the emitter layer is formed. The textured surface includes a plurality of depressions. A surface of an area of the substrate, on which the first electrode part is formed, is a flat surface not including the plurality of depressions.

This application claims priority to and the benefit of Korean Patent Application No. 10-2010-0069960 filed in the Korean Intellectual Property Office on Jul. 20, 2010 and Korean Patent Application No. 10-2010-0094611 filed in the Korean Intellectual Property Office on Sep. 29, 2010, the entire contents of which are incorporated herein by reference.

### BACKGROUND OF THE INVENTION

1. Field of the Invention

Embodiments of the invention relate to a solar cell and a method for manufacturing the same.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted because the solar cells derive electric energy from an abundant energy source and do not cause environmental pollution.

The solar cells are classified into a crystalline silicon solar cell, an amorphous silicon solar cell, and a compound solar cell based on kinds of materials used. The crystalline silicon solar cell is further classified into a single crystal silicon solar cell and a polycrystalline silicon solar cell.

Because the single crystal silicon solar cell has a good-quality substrate, it is easy to achieve high efficiency of the single crystal silicon solar cell. However, the manufacturing cost of the single crystal silicon solar cell increases when using the good-quality substrate. On the other hand, because a substrate of the polycrystalline silicon solar cell is poorer than the substrate of the single crystal silicon solar cell in quality, it is more difficult to achieve the high efficiency of the polycrystalline silicon solar cell than the single crystal silicon solar cell. However, as the quality of the substrate and the process technology of the polycrystalline silicon solar cell have been greatly improved, the efficiency of the polycrystalline silicon solar cell has recently increased.

Examples of methods for achieving the high efficiency of the polycrystalline silicon solar cell include a method for forming uneven portions on a light receiving surface of the substrate to reduce a reflectance of light incident on the light receiving surface.

### SUMMARY OF THE INVENTION

Embodiments of the invention provide a solar cell with improved efficiency.

Embodiments of the invention also provide a method for manufacturing a solar cell capable of reducing process time.

In one aspect, there is a solar cell including a substrate, an emitter layer formed at an incident surface of the substrate, a first electrode part connected to the emitter layer, and a textured surface positioned on the incident surface of the substrate, at which the emitter layer is formed, the textured surface including a plurality of depressions, wherein a surface of an area of the substrate, on which the first electrode part is formed, is a flat surface not including the depression.

The textured surface includes a plurality of depressions of a semicircle cross-sectional shape each having a diameter equal to or less than about 10 μm.

The first electrode part includes a plurality of first electrodes, a plurality of first electrode current collectors crossing the plurality of first electrodes, or both. The plurality of first electrodes, the plurality of first electrode current collectors, or both are formed on the flat surface.

The solar cell may further include an anti-reflection layer positioned on the emitter layer and a second electrode part positioned on a surface opposite the incident surface of the substrate.

In another aspect, there is a method for manufacturing a solar cell including providing a substrate, disposing a mask having a plurality of hole patterns on the substrate, irradiating a linear laser beam onto an incident surface of the substrate using the mask and forming a plurality of depressions on the incident surface of the substrate to thereby form a textured surface that corresponds to the plurality of the hole patterns, forming an emitter layer at the substrate, forming an anti-reflection layer on the emitter layer, forming a first electrode part, which passes through the anti-reflection layer and is connected to the emitter layer, and forming a second electrode part on a back surface of the substrate.

The forming of the emitter layer may be performed before forming the textured surface or after forming the textured surface.

The forming of the emitter layer includes coating a paste containing impurities or a solution containing impurities on the incident surface of the substrate to form an impurity layer, or performing an ion implantation process to inject the impurities into the incident surface of the substrate. An activation process for diffusing the impurities from the coating to the substrate may be performed simultaneously with the irradiating of the linear laser beam.

To simultaneously perform the activation process of the impurities and the process for irradiating the linear laser beam, the mask may include a permeable area, in which the plurality of hole patterns are formed, and a semipermeable area, in which a semipermeable pattern for reducing an intensity of the linear laser beam is formed. The linear laser beam may have a line width that simultaneously irradiates the plurality of hole patterns and the semipermeable pattern.

The forming of the textured surface includes, before irradiating the linear laser beam, transferring the substrate by a width of the permeable area to adjust a relative location between the mask and the substrate.

The linear laser beam may use an excimer laser having a wavelength equal to or less than about 500 nm. The line width of the linear laser beam may be greater than a width of each hole pattern.

The forming of the textured surface may include transferring the substrate to adjust a relative location between the mask and the substrate.

Turn-on and turn-off operations of the linear laser beam may be controlled, so as to form a surface of an area of the substrate, on which the first electrode part is to be formed, as a flat surface.

Alternatively, the mask may include a light shielding pattern at a location corresponding to a formation area of the first electrode part, and the surface of the area of the substrate, on which the first electrode part is to be formed, may be formed as a flat surface using the light shielding pattern.

According to the above-described characteristics, a plurality of depressions may be simultaneously formed using a linear laser beam having a constant line width.

In the embodiment of the invention, the size of the depression may be reduced to be equal to or less than about 10 μm, as compared to the related art, that forms a mask pattern using a spot laser and then performs an etching process using the mask pattern, thereby forming depressions. Thus, a large number of depressions can be formed, and a light reflectance of the textured surface can be efficiently reduced by the depressions.

A reduction in the uniformity of the depression patterns resulting from pulse-to-pulse variation of the laser beam may be suppressed, and the process time may be reduced.

Furthermore, because the textured surface and the emitter layer may be simultaneously formed, the process time may be further reduced.

Furthermore, because the surface of the emitter layer, on which the first electrode part is formed, is formed substantially evenly, an increase in a contact resistance between metal and silicon may be prevented or reduced. Because the turn-on and turn-off operations of the linear laser beam are controlled, an amount of the linear laser beam used may be reduced.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a partial prospective view of a solar cell according to an example embodiment of the invention;

FIG. 2 is a cross-sectional view taken along lines II-II of FIG. 1;

FIGS. 3 to 7 are partial plane views illustrating various configurations of a textured surface of a substrate;

FIG. 8 is a partial plane view of a mask used to form a textured surface;

FIG. 9 is a partial plane view of a mask used to form a textured surface and an emitter layer;

FIG. 10 illustrates a solar cell manufacturing device according to an example embodiment of the invention;

FIG. 11 illustrates a process for forming a textured surface using a mask shown in FIG. 8; and

FIG. 12 illustrates a process for forming a textured surface and an emitter layer using a mask shown in FIG. 9.

### DETAILED DESCRIPTION OF THE EMBODIMENTS

Embodiments of the invention will be described more fully hereinafter with reference to the accompanying drawings, in which example embodiments of the invention are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

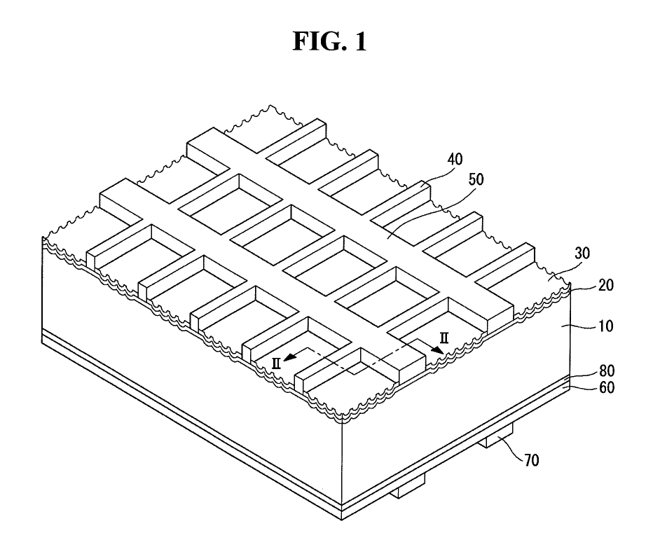

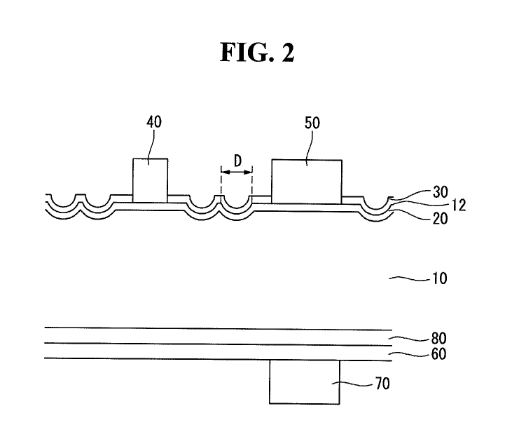

A solar cell according to an example embodiment of the invention is described in detail with reference to FIGS. 1 and 2.

FIG. 1 is a partial prospective view of a solar cell according to an example embodiment of the invention. FIG. 2 is a cross-sectional view taken along lines II-II of FIG. 1.

As shown in FIGS. 1 and 2, a solar cell according to an example embodiment of the invention includes a substrate 10, an emitter layer 20 positioned at a front surface (hereinafter, referred to as ‘a light receiving surface’) of the substrate 10 on which light is incident, an anti-reflection layer 30 positioned on the emitter layer 20, first electrode parts 40 and 50 electrically connected to the emitter layer 20, second electrode parts 60 and 70 positioned on a back surface opposite the front surface of the substrate 10, and a back surface field (BSF) layer 80 positioned at the back surface of the substrate 10.

The first electrode parts 40 and 50 include a plurality of first electrodes 40 positioned on the front surface of the substrate 10 and a plurality of first electrode current collectors 50 electrically and physically connected to the plurality of first electrodes 40. Further, the second electrode parts 60 and 70 include a second electrode 60 positioned on the back surface of the substrate 10 and a second electrode current collector 70 electrically and physically connected to the second electrode 60.

The substrate 10 is a semiconductor substrate formed of first conductive type silicon, for example, p-type silicon, though not required. Silicon used in the substrate 10 may be single crystal silicon, polycrystalline silicon, or amorphous silicon. When the substrate 10 is of a p-type, the substrate 10 may contain impurities of a group III element such as boron (B), gallium (Ga), and indium (In). Alternatively, the substrate 10 may be of an n-type and/or be formed of other semiconductor materials other than silicon. When the substrate 10 is of the n-type, the substrate 10 may contain impurities of a group V element such as phosphorus (P), arsenic (As), and antimony (Sb).

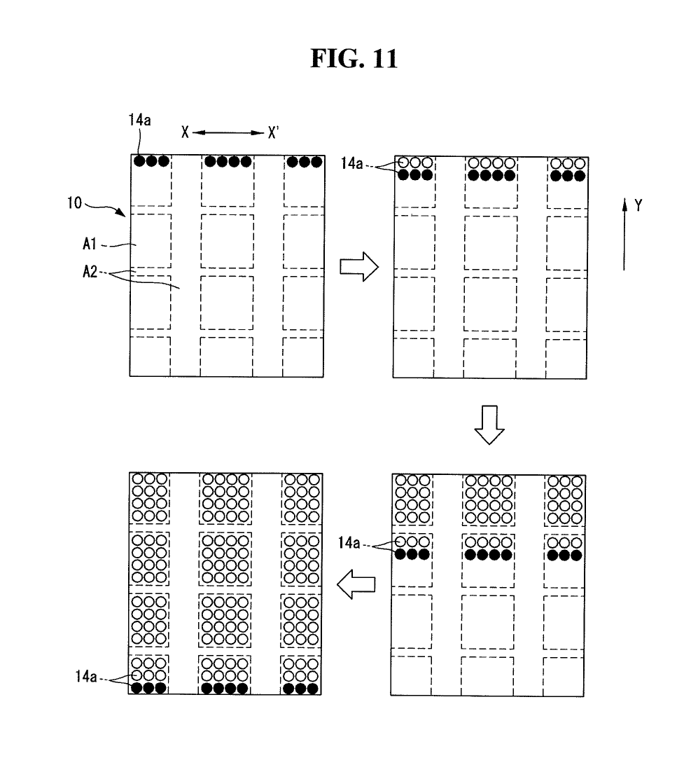

As shown in FIG. 11, the substrate 10 includes a first area A1 and a second area A2. The second area A2 indicates a formation area of the first electrode parts 40 and 50, and the first area A1 indicates an area excluding the second area A2 from the entire area of the substrate 10. In embodiments of the invention, portions of the first area A1 are discontinuous, while portions of the second area A2 are continuous. The discontinuous portions of the first area A1 may have the same shape, while the portions of the second area may have different shapes. The portions of the first area are divided or delineated by the second area A2.

In the embodiment of the invention, the first area A1 of the substrate 10 has a textured surface 12, so as to reduce a reflectance of light incident on the light receiving surface of the substrate 10. The textured surface 12 may have a honeycomb structure in which a plurality of depressions are formed at the surface of the substrate 10. Each of the plurality of depressions may have a semicircle cross-sectional shape, and the size, i.e., a diameter of each depression is equal to or less than about 10 μm. In embodiments of the invention, a shape of the plurality of depressions may be hemisphere or a crater. Other shapes are possible, including a polyhedron, and others such as a cylinder.

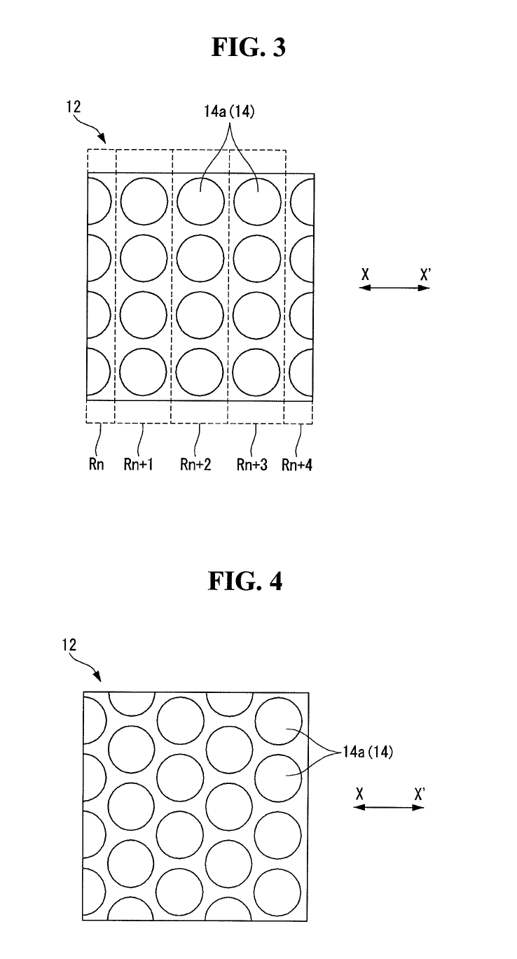

FIGS. 3 to 7 are partial plane views illustrating various configurations of the textured surface 12 of the substrate 10.

As shown in FIG. 3, a plurality of depressions 14a constituting the textured surface 12 are arranged in a plurality of columns . . . , Rn, Rn+1, Rn+2, Rn+3, Rn+4, . . .

The depressions 14a positioned on each column may have substantially the same size. All of the plurality of depressions 14a arranged in the plurality of columns may have substantially the same size. The depressions 14a positioned on one column and the depressions 14a positioned on other column adjacent to the one column are arranged parallel to one another in a row direction X-X′. In this instance, the depressions 14a in the column direction (a first direction) may be arranged perpendicularly from the depressions in a row direction (a second direction).

As shown in FIG. 4, all of the plurality of depressions 14a arranged in the plurality of columns may have substantially the same size. The depressions 14a positioned on one column and the depressions 14a positioned on other column adjacent to the one column are arranged non-parallel to one another in the row direction X-X′. In this instance, the depressions 14a in the column direction (the first direction) may be arranged at an angle from the depressions 14a in a row direction that is inclined (a third direction). The inclined rows of the depressions 14a may be parallel to each other. An angle between at least one of the columns and at least one of the inclined rows may be about 30° to 60°.

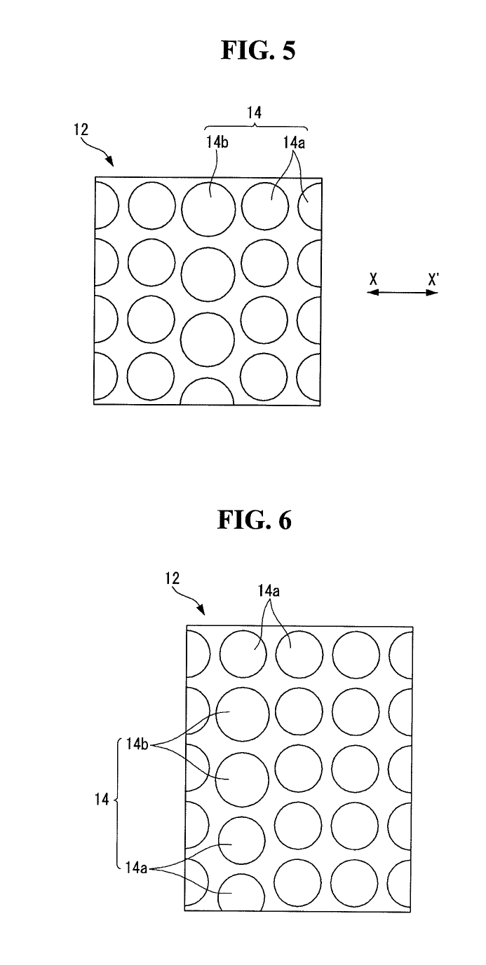

As shown in FIG. 5, the depressions positioned on respective columns have substantially the same size. On the other hand, sizes of the depressions positioned on one column of the plurality of columns may be different from sizes of the depressions positioned on at least one other column.

For example, sizes of depressions 14b positioned on a middle column of the plurality of columns shown in FIG. 5 are larger than sizes of depressions 14a positioned on other column. The number of columns, in which the larger-sized depressions 14b are arranged, is not limited, and also an arrangement location of the columns, in which the larger-sized depressions 14b are arranged, may vary. According to the configuration illustrated in FIG. 5, the depressions 14b positioned on one column and the depressions 14a positioned on other column adjacent to the one column are arranged non-parallel to one another in the row direction X-X′. In this instance, the columns having all depressions 14a and the columns having all larger-sized depressions 14b may alternate.

As shown in FIG. 6, depressions having at least two different sizes are arranged on one column. For example, sizes of depressions 14b, that are positioned on a second column and on second and third rows from the top, are larger than sizes of depressions 14a, that are positioned on the second column and rows other than the second and third rows. The number of larger-sized depressions 14b on one column is not limited. An arrangement location of the larger-sized depressions 14b may vary.

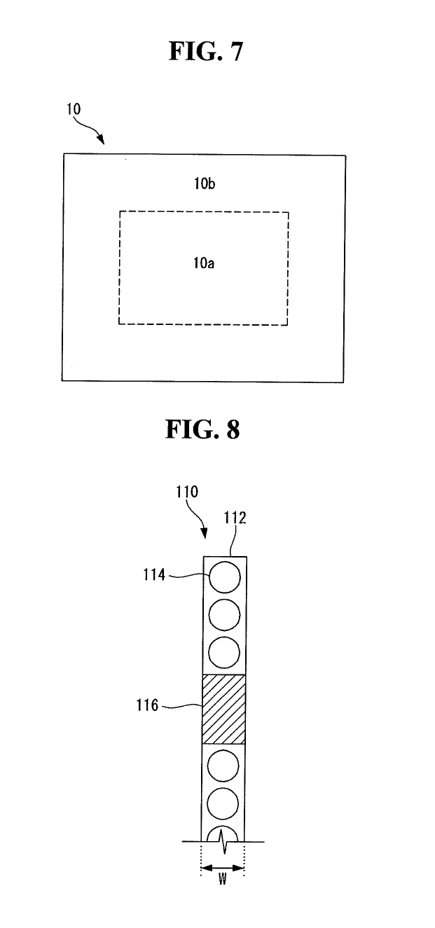

As shown in FIG. 7, when the plurality of depressions positioned on one column of the plurality of columns have at least two different sizes, sizes of depressions, that are positioned in a middle portion 10a of the substrate 10 on the one column, may be different from sizes of depressions, that are positioned in an edge portion 10b of the substrate 10 on the one column.

For example, the size of the depression positioned in the middle portion 10a of the substrate 10 may be greater than the size of the depression positioned in the edge portion 10b of the substrate 10. In this instance, the sizes of the depressions may increase as the locations of the depressions go from the edge portion 10b of the substrate 10 to the middle portion 10a of the substrate 10. Such an increase in the size of the depression at different locations of the substrate may be gradual or in one or more steps.

On the contrary, the size of the depression positioned in the edge portion 10b of the substrate 10 may be greater than the size of the depression positioned in the middle portion 10a of the substrate 10. In this instance, the sizes of the depressions may increase as the locations of the depressions go from the middle portion 10a of the substrate 10 to the edge portion 10b of the substrate 10. Such an increase in the size of the depression at different locations of the substrate may be gradual or in one or more steps.

FIGS. 3 to 7 illustrated only the several example configurations of the textured surface 12. However, the embodiments of the invention are not limited thereto, and various configurations may be used for the textured surface 12. For example, the plurality of depressions may be arranged in the plurality of columns or may be non-uniformly arranged.

More specifically, when the plurality of depressions are arranged in the plurality of columns, the depressions positioned on one column of the plurality of columns may have substantially the same size, or may have at least two different sizes.

When the depressions positioned on the one column have substantially the same size, the sizes of the depressions positioned on the one column may be substantially equal to or different from the sizes of the depressions positioned on at least one other column.

When the sizes of the depressions positioned on the one column are different from the sizes of the depressions positioned on the other column, the depressions positioned on the one column and the depressions positioned on the other column may be arranged non-parallel to one another in the row direction.

When all of the plurality of depressions arranged in the plurality of columns have substantially the same size, the depressions positioned on one column and the depressions positioned on other column adjacent to the one column may be arranged parallel to one another in the row direction or may be arranged non-parallel to one another in the row direction.

When the depressions positioned on one column of the plurality of columns have at least two different sizes, the sizes of the depressions, that are positioned in a middle portion of the substrate on the one column, may be different from the sizes of the depressions, that are positioned in an edge portion of the substrate on the one column.

For example, the size of the depression positioned in the middle portion of the substrate may be greater than the size of the depression positioned in the edge portion of the substrate. In this instance, the sizes of the depressions may increase as the locations of the depressions go from the edge portion of the substrate to the middle portion of the substrate. Such an increase in the size of the depression at different locations of the substrate may be gradual or in one or more steps.

On the contrary, the size of the depression positioned in the edge portion of the substrate may be greater than the size of the depression positioned in the middle portion of the substrate. In this instance, the sizes of the depressions may increase as the depressions go from the middle portion of the substrate to the edge portion of the substrate. Such an increase in the size of the depression at different locations of the substrate may be gradual or in one or more steps.

When the plurality of depressions are non-uniformly arranged, the plurality of depressions may have substantially the same size, or may have at least two different sizes.

The emitter layer 20 is positioned in the first area A1 and the second area A2 of the substrate 10.

The emitter layer 20 is a region of the substrate 10 that is doped with impurities of a second conductive type (for example, an n-type) opposite the first conductive type of the substrate 10. The emitter layer 20 forms a p-n junction along with the substrate 10. Because the emitter layer 20 is formed by the diffusion of the impurities into the substrate 10, the emitter layer 20 formed on the front surface of the substrate 10 has substantially the same shape as the surface of the substrate 10. Namely, a lower surface of the emitter layer 20 has substantially the same depressions as the textured surface 12 in the first area A1 of the substrate 10, and is substantially flat in the second area A2 of the substrate 10.

A plurality of electron-hole pairs produced by light incident on the substrate 10 are separated into electrons and holes by a built-in potential difference resulting from the p-n junction between the substrate 10 and the emitter layer 20. The separated electrons move to the n-type semiconductor, and the separated holes move to the p-type semiconductor. When the substrate 10 is of the p-type and the emitter layer 20 is of the n-type, the separated holes move to the substrate 10 and the separated electrons move to the emitter layer 120. Accordingly, the holes become major carriers in the substrate 10, and the electrons become major carriers in the emitter layer 20.

Because the emitter layer 20 forms the p-n junction along with the substrate 10, the emitter layer 20 is of the p-type when the substrate 10 is of the n-type. In this instance, the separated electrons move to the n-type substrate 10 and the separated holes move to the p-type emitter layer 20.

When the emitter layer 20 is to be of the n-type, the emitter layer 20 may be formed by doping the substrate 10 with impurities of a group V element such as phosphor (P), arsenic (As), and antimony (Sb). On the contrary, when the emitter layer 20 is to be of the p-type, the emitter layer 20 may be formed by doping the substrate 10 with impurities of a group III element such as boron (B), gallium (Ga), and indium (In).

The anti-reflection layer 30 on the emitter layer 20 positioned in the first area A1 of the substrate 10 may be formed of silicon nitride (SiNx) and/or silicon dioxide (SiO₂). The anti-reflection layer 30 reduces a reflectance of light incident on the solar cell and increases a selectivity of a predetermined wavelength band of the incident light, thereby increasing the efficiency of the solar cell.

The first electrode part including the plurality of first electrodes 40 and the plurality of first electrode current collectors 50 is positioned in the second area A2 of the substrate 10. The substrate surface in the second area A2 is substantially flat.

In the embodiment of the invention, the substantially flat surface of the substrate 10 indicates that there is no depression on the surface of the substrate 10. Thus, any roughness of the substantially flat surface of the substrate 10 may be negligible.

When the substrate surface in the second area A2 is substantially flat, a contact surface between the first electrode part positioned in the second area A2 and the substrate surface in the second area A2 is substantially flat. Thus, an increase in a contact resistance between metal forming the first electrode part and silicon forming the substrate 10 may be prevented or reduced.

A width of the second area A2 may be substantially equal to a width of the first electrode part, or may be greater than the width of the first electrode part.

The plurality of first electrodes 40 are positioned on the emitter layer 20 of the second area A2 and are electrically connected to the emitter layer 20. Further, the plurality of first electrodes 40 extend in a fixed direction in a state where the first electrodes 40 are spaced apart from one another. The first electrodes 40 collect carriers (for example, electrons) moving to the emitter layer 20 and output the carriers to an external device.

The first electrodes 40 may be formed of at least one conductive material selected from the group consisting of silver (Ag), nickel (Ni), copper (Cu), aluminum (Al), tin (Sn), zinc (Zn), indium (In), titanium (Ti), gold (Au), and a combination thereof. Other conductive materials may be used for the first electrodes 40.

The plurality of first electrode current collectors 50 are formed on the emitter layer 20 of the second area A2 in a direction crossing the first electrodes 40. The first electrode current collectors 50 are electrically and physically connected to the first electrodes 40. Thus, the first electrode current collectors 50 output carriers (for example, electrons) transferred from the first electrodes 40 to the external device.

The second electrode 60 is formed on the entire back surface of the substrate 10 except an edge of the substrate 10. Alternatively, the second electrode 60 may be formed in an area excluding a formation area of the second electrode current collector 70 from the back surface of the substrate 10. The second electrode 60 contains a conductive material such as aluminum (Al) and is electrically connected to the substrate 10. Further, the second electrode 60 collects carriers (for example, holes) moving to the substrate 10 and outputs the carriers to the external device. The second electrode 60 may contain at least one conductive material selected from the group consisting of Ni, Cu, Ag, Sn, Zn, In, Ti, Au, and a combination thereof, in addition to Al. Other conductive materials may be used for the second electrode 60.

The second electrode current collector 70 positioned on the back surface of the second electrode 60 is formed in the same direction as the first electrode current collectors 50. The second electrode current collector 70 outputs carriers (for example, holes) transferred from the second electrode 60 to the external device.

When the second electrode 60 is formed in the area excluding the formation area of the second electrode current collector 70 from the back surface of the substrate 10, the second electrode current collector 70 may be formed to contact the back surface of the substrate 10.

The back surface field layer 80 positioned between the second electrode 60 and the substrate 10 is a region (for example, a p⁺-type region) that is more heavily doped with impurities of the same conductive type as the substrate 10 than the substrate 10.

The movement of electrons to the back surface of the substrate 10 may be prevented or reduced by a potential barrier resulting from a difference between impurity concentrations of the substrate 10 and the back surface field layer 80. Hence, a recombination and/or a disappearance of electrons and holes around the back surface of the substrate 10 may be prevented or reduced.

A method for manufacturing the solar cell according to the example embodiment of the invention is described below with reference to FIGS. 8 to 12.

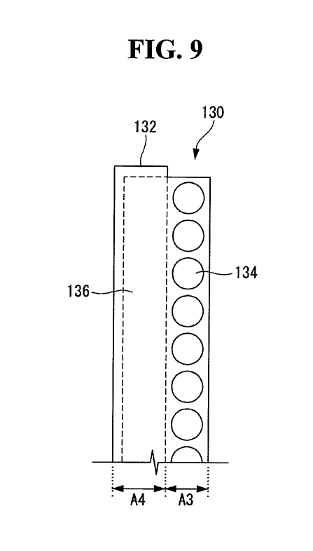

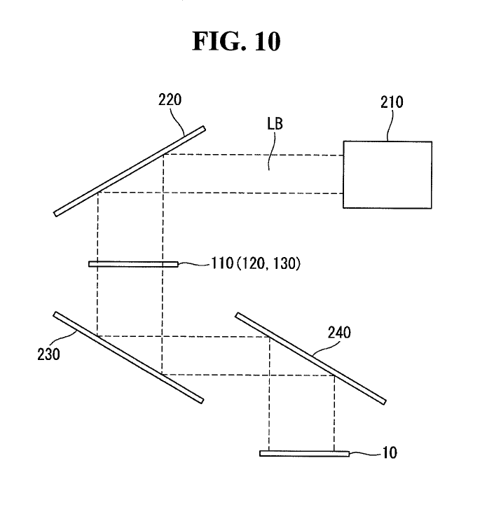

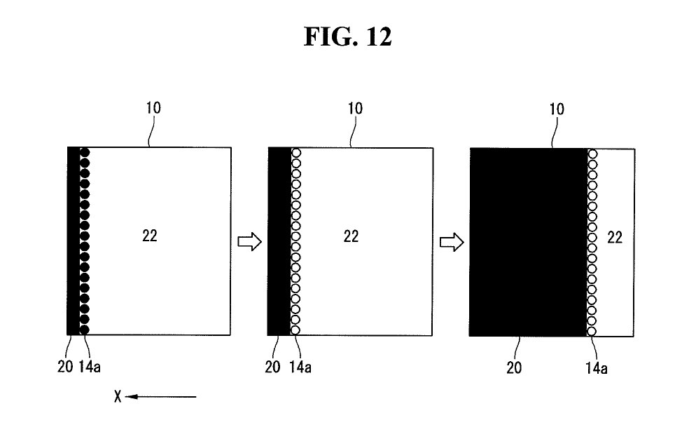

FIG. 8 is a partial plane view of a mask used to form the textured surface. FIG. 9 is a partial plane view of a mask used to simultaneously form the textured surface and the emitter layer. FIG. 10 illustrates a solar cell manufacturing device. FIG. 11 illustrates a process for forming the textured surface using the mask shown in FIG. 8. FIG. 12 illustrates a process for forming the textured surface and the emitter layer using the mask shown in FIG. 9.

As shown in FIGS. 8, 10, and 11, a mask 110 according to the example embodiment of the invention has a plurality of hole patterns 114 and a light shielding pattern 116 in one slit 112. The plurality of hole patterns 114 are arranged in one column, and each hole pattern 114 has a size (i.e., a diameter) equal to or less than about 10 μm.

In the embodiment of the invention, the plurality of hole patterns 114 pass through a laser beam and are used to form the plurality of depressions 14 in the first area A1 of the substrate 10. The light shielding pattern 116 shields the laser beam and makes or maintains the substrate surface of the second area A2 substantially flat.

The mask 110 having the above-described configuration is disposed between a first reflection mirror 220 and a second reflection mirror 230 of a solar cell manufacturing device shown in FIG. 11.

A laser beam LB output from a laser source 210 is a linear laser beam having a constant line width and also is an excimer laser having a wavelength equal to or less than about 500 nm. The laser beam LB has the same shape as or a shape similar to the mask 110.

The line width of the laser beam LB may be greater than the size (i.e., the diameter) of the hole pattern 114 and may be equal to or less than a width W of the slit 112. For example, the line width of the laser beam LB may be several μm to about 20 μm. The line width of the laser beam LB may be adjusted using a short axis beam cutter.

It is preferable, but not required, that a length of the laser beam LB is equal to or slightly less than a length of the substrate 10 or a length of the mask 110. The length of the laser beam LB may be adjusted using a beam cutter disposed on the mask 110.

The mask 110 is disposed between the first reflection mirror 220 and the second reflection mirror 230 in a state where a length direction of the laser beam LB is substantially the same as a length direction of the slit 112, so that only a portion of the laser beam LB can pass through the hole patterns 114 of the mask 110. The mask 110 is long disposed or extends in a row direction X-X′ of the substrate 10 shown in FIG. 11.

In the solar cell manufacturing device having the above-described configuration, a portion of the laser beam LB output from the laser source 210 is reflected from the first reflection mirror 220 and passes through the hole patterns 114 of the mask 110. The portion of the laser beam LB then is reflected from the second reflection mirror 230 and a third reflection mirror 240 and is incident on a substrate 10.

Thus, a portion of the surface in the first area A1 of the substrate 10, on which the laser beam LB is incident, is removed, thereby forming a plurality of depressions each having a circle cross-sectional shape (for example, the depressions 14a and 14b shown in FIGS. 3 to 6) in the first area A1. In this instance, as shown in FIG. 12, the depressions (for example, the depressions 14a and 14b shown in FIGS. 3 to 6) are arranged at the surface of the substrate 10 in one column in the same manner as the hole patterns 114 of the mask 110.

The portion of the laser beam LB irradiated onto the light shielding pattern 116 among the laser beam LB irradiated onto the mask 110 is shielded by the light shielding pattern 116. Thus, as shown in FIG. 11, because the laser beam LB is not irradiated in an area to be formed with the first electrode current collectors 50, the substrate surface of the second area A2 is substantially flat.

Next, after the substrate 10 is transferred by a predetermined distance in an arrow direction (i.e., a Y-axis direction), the above-described process is repeatedly performed. Hence, the plurality of depressions are formed in the first area A1 of the substrate 10, for example, in a sequential manner. As a result, a textured surface (for example, the textured surface 12 shown in FIGS. 2 to 6) including the plurality of depressions is completed in the first area A1 of the substrate 10.

When the textured surface is formed while the substrate 10 is transferred in the arrow direction, the textured surface does not have to be formed in the area of the substrate 10, on which the first electrodes 40 will be formed.

For this, in the embodiment of the invention, turn-on and turn-off operations of the laser beam LB are controlled. Namely, the texturing process is performed directly before reaching the area of the substrate 10 to be formed with the first electrodes 40, and then the laser beam LB is turned off for a predetermined time when the area of the substrate 10 to be formed with the first electrodes 40 would have been subject to irradiation by the laser beam LB. After a predetermined time had passed, the laser beam LB is again turned on to perform the texturing process.

According to the above-described method, the light shielding pattern 116 shields the laser beam LB in a portion of the second area A2, on which the first electrode current collectors 50 will be formed, and thus the textured surface is not formed in the portion of the second area A2 to be formed with the first electrode current collectors 50. Further, the laser beam LB is turned off over a portion of the second area A2 to be formed with the first electrodes 40 when the laser beam would have been irradiated on the portion of the second area A2 to be formed with the first electrodes 40, and thus the textured surface is not formed in the portion of the second area A2 to be formed with the first electrodes 40.

An amount of the laser beam LB used may be reduced by controlling the turn-on and turn-off operations of the laser beam LB.

Further, the portion of the second area A2 to be formed with the first electrodes 40 may be formed using the light shielding pattern 116.

In FIG. 11, a white circle denotes the depression, that has been formed in a previous process, and a black circle denotes the depression, that is formed in a current process.

After the textured surface is formed in the first area A1 of the substrate 10, an emitter layer (for example, the emitter layer 20 shown in FIGS. 1 and 2) is formed.

The emitter layer may be formed by coating a paste containing impurities or a solution containing impurities on the first and second areas of the substrate to form an impurity layer and performing thermal processing on the impurity layer to diffuse the impurities into the substrate.

Alternatively, the emitter layer may be formed by injecting impurities into the substrate using an ion implantation method.

Alternatively, before the textured surface is formed, the emitter layer may be formed using at least one of the above-described methods.

Another method for manufacturing the solar cell according to the example embodiment of the invention is described below with reference to FIGS. 9, 11, and 12.

In a mask 130 shown in FIG. 9, one slit 132 is divided into a permeable area A3 and a semipermeable area A4, a plurality of hole patterns 134 are formed in the permeable area A3, and a semipermeable pattern 136 is formed in the semipermeable area A4. Accordingly, the slit 132 includes the hole patterns 134 and the semipermeable pattern 136.

The semipermeable pattern 136 is a pattern for reducing an intensity of the laser beam LB to about 30% to 50% to thereby activate impurities of an impurity layer. It is preferable, but not required, that the semipermeable pattern 136 has substantially the same size as the permeable area A3.

It is preferable, but not required, that a line width of the laser beam LB is greater than a size capable of simultaneously irradiating the laser beam LB onto the hole patterns 134 and the semipermeable pattern 136, and is equal to or less than a width of the slit 132. In other embodiments of the invention, the line width of the laser beam LB may be equal to or less than a width of at least one of the permeable area A3 and the semipermeable area A4. A width of the permeable area A3 may be the same or smaller than a width of the semipermeable area A4.

In the embodiment of the invention, a process for forming the textured surface is performed in a state where an impurity layer 22 for forming the emitter layer (for example, the emitter layer 20 shown in FIGS. 1 and 2) was previously coated on the surface of the substrate 10.

More specifically, depressions of a first column are formed at the surface of the substrate 10 by the laser beam LB, that is reflected from the first reflection mirror 220 and passes through the hole patterns 134.

Next, the substrate 10 is transferred by a width of the permeable area A3 in the arrow direction (i.e., the X-axis direction), and then the laser beam LB is again irradiated onto the substrate 10.

When the laser beam LB is irradiated, the laser beam LB passing through the semipermeable pattern 136 is irradiated into an area of the substrate 10 corresponding to the first column. Therefore, the impurities of the impurity layer 22 coated in the area of the first column are activated and are diffused into the substrate 10. Thus, the emitter layer is formed in the area of the first column. It is a matter of course that the plurality of depressions have been already formed in the area of the first column in a previous process.

Next, depressions of a second column are formed by the laser beam LB passing through the hole patterns 134.

As described above, the textured surface 12 is formed at the surface of the substrate 10 by repeatedly performing the transfer operation of the substrate 10 and the irradiation operation of the laser beam LB, and the emitter layer 20 inside the substrate 10 is formed under the textured surface 12.

Because the mask 130 used in the manufacturing method according to the embodiment of the invention does not have the light shielding pattern, the textured surface may be formed in the second area of the substrate when the textured surface is formed using the mask 130 shown in FIG. 9.

However, when the light shielding pattern is formed in the permeable area A3 of the mask 130 shown in FIG. 9, the textured surface may be formed only on the substrate surface of the first area while the texturing process and the activation process of the impurities are simultaneously performed.

In embodiments of the invention, reference to a flat surface relate to a surface that is intentionally without the depressions 14, 14a and/or 14b. Additionally, on areas of the substrate 10 with the depressions 14, 14a and/or 14b are formed, the depressions 14, 14a and/or 14b may be arranged in a predetermined pattern or patterns.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell comprising:
a substrate;
an emitter layer formed at an incident surface of the substrate;
a first electrode part connected to the emitter layer; and
a textured surface positioned on the incident surface of the substrate, at which the emitter layer is formed, the textured surface including a plurality of depressions,
wherein a surface of an area of the substrate, on which the first electrode part is formed, is a flat surface not including the plurality of depressions.

2. The solar cell of claim 1, wherein the textured surface includes a plurality of depressions of a semicircle cross-sectional shape each having a diameter equal to or less than about 10 μm.

3. The solar cell of claim 1, wherein the first electrode part includes a plurality of first electrodes, a plurality of first electrode current collectors crossing the plurality of first electrodes, or both.

4. The solar cell of claim 3, wherein the plurality of first electrodes, the plurality of first electrode current collectors, or both are formed on the flat surface.

5. The solar cell of claim 1, further comprising:
an anti-reflection layer positioned on the emitter layer; and
a second electrode part positioned on a surface opposite the incident surface of the substrate.

6. A method for manufacturing a solar cell comprising:
providing a substrate;
disposing a mask having a plurality of hole patterns on the substrate;
irradiating a linear laser beam onto an incident surface of the substrate using the mask and forming a plurality of depressions on the incident surface of the substrate to thereby form a textured surface that corresponds to the plurality of the hole patterns;
forming an emitter layer at the substrate;
forming an anti-reflection layer on the emitter layer;
forming a first electrode part, which passes through the anti-reflection layer and is connected to the emitter layer; and
forming a second electrode part on a back surface of the substrate.

7. The method of claim 6, wherein the forming of the emitter layer is performed before forming the textured surface.

8. The method of claim 6, wherein the forming of the emitter layer is performed after forming the textured surface.

9. The method of claim 8, wherein the forming of the emitter layer includes coating a paste containing impurities or a solution containing impurities on the incident surface of the substrate to form an impurity layer, or performing an ion implantation process to inject the impurities into the incident surface of the substrate.

10. The method of claim 9, wherein an activation process for diffusing the impurities from the coating into the substrate is performed simultaneously with the irradiating of the linear laser beam.

11. The method of claim 10, wherein the mask includes a permeable area, in which the plurality of hole patterns are formed, and a semipermeable area, in which a semipermeable pattern for reducing an intensity of the linear laser beam is formed.

12. The method of claim 11, wherein the linear laser beam has a line width that simultaneously irradiates the plurality of hole patterns and the semipermeable pattern.

13. The method of claim 12, wherein the forming of the textured surface includes, before irradiating the linear laser beam, transferring the substrate by a width of the permeable area to adjust a relative location between the mask and the substrate.

14. The method of claim 6, wherein the linear laser beam uses an excimer laser having a wavelength equal to or less than about 500 nm.

15. The method of claim 14, wherein a line width of the linear laser beam is greater than a width of each hole pattern.

16. The method of claim 6, wherein the forming of the textured surface includes transferring the substrate to adjust a relative location between the mask and the substrate.

17. The method of claim 6, further comprising controlling turn-on and turn-off operations of the linear laser beam to form a surface of an area of the substrate, on which the first electrode part is to be formed, as a flat surface.

18. The method of claim 6, wherein the mask includes a light shielding pattern at a location corresponding to a formation area of the first electrode part to form a surface of an area of the substrate, on which the first electrode part is to be formed, as a flat surface using the light shielding pattern.

19. A solar cell comprising:
a substrate;
an emitter layer formed at an incident surface of the substrate;
a first electrode part connected to the emitter layer;
a first area of the incident surface of the substrate, at which the emitter layer is formed, the first area including a plurality of depressions; and
a second area of the incident surface of the substrate, at which the emitter layer is formed, on which the first electrode part is formed, is a flat surface not including the plurality of depressions.

20. The solar cell of claim 19, wherein the first area includes a plurality of discontinuous areas each having the depressions, the plurality of discontinuous areas being delineated by the second area.
